(19) United States
(12) Patent Application Publication
(10) Pub. No.: US 2024/0376589 A1
(43) Pub. Date: Nov. 14, 2024

(54) DEPOSITION SOURCE

(71) Applicant: Samsung Display Co., LTD., Yongin-si (KR)

(72) Inventors: SANGMIN JUNG, Yongin-si (KR); MIN- GYU SEO, Yongin-si (KR); EUGENE KANG, Yongin-si (KR); HWAPYEONG JEONG, Yongin-si (KR); DONGKIUN SEO, Yongin-si (KR); CHULHWAN AN, Yongin-si (KR)

(21) Appl. No.: 18/654,930

(22) Filed: May 3, 2024

(30) Foreign Application Priority Data
May 11, 2023 (KR) 10-2023-0061120

(51) Int. Cl. C23C 14/24; C23C 14/54

(52) U.S. Cl. CPC C23C 14/243; C23C 14/54

(57) ABSTRACT

A deposition source includes a crucible, a plurality of nozzles, a housing, a lower heater module, an upper heater module, a first electrode, a second electrode, and a power supply. The crucible accommodates a deposition material. The plurality of nozzles is disposed on the crucible and spaced apart from each other along a first direction. The housing accommodates the crucible and the plurality of nozzles. The lower heater module is disposed in an inner space of the housing to surround the crucible. The upper heater module is disposed on the lower heater module. The first electrode extends in a second direction crossing the first direction and is connected to the lower heater module. The second electrode extends in the second direction. The second electrode is connected to the upper heater module. The power supply is electrically connected to the first electrode and the second electrode.

This application claims priority to Korean Patent Application No. 10-2023-0061120, filed on May 11, 2023, and all the benefits accruing therefrom under 35 U.S.C. § 119, the content of which in its entirety is herein incorporated by reference.

### BACKGROUND

### 1. Field

The disclosure relates to a deposition source, and more particularly to a linear deposition source.

### 2. Description of the Related Art

A display device may include a plurality of thin films. Each of the plurality of thin films may be formed by a vacuum deposition method, an ion plating method, a physical vapor deposition method, a chemical vapor deposition method, or the like.

A deposition apparatus for performing the vacuum deposition method may include a deposition source. The deposition source may include a crucible capable of storing a deposition material, a heater capable of heating the crucible, a nozzle through which the deposition material is emitted, or the like.

If a temperature of the heater is outside a set range, a film thickness of each of the plurality of thin films may deviate from a reference thickness. For example, when the temperature of the heater is excessively high, the film thickness may be formed to be thicker than the reference thickness. On the other hand, when the temperature of the heater is excessively low, the film thickness may be formed to be thinner than the reference thickness.

### SUMMARY

The present invention relates to a deposition source with an improved temperature gradient.

Embodiments of a deposition source include a crucible that accommodates a deposition material, a plurality of nozzles disposed on the crucible and spaced apart from each other along a first direction, a housing accommodating the crucible and the plurality of nozzles, a lower heater module disposed in an inner space of the housing and surrounding the crucible, an upper heater module disposed on the lower heater module in the inner space of the housing, a first electrode extending in a second direction crossing the first direction and connected to the lower heater module, a second electrode extending in the second direction and connected to the upper heater module, and a power supply electrically connected to the first electrode and the second electrode.

In an embodiment, the upper heater module may include a first upper heater module and a second upper heater module. The first upper heater module and the second upper heater module may be spaced apart from each other in the first direction.

In an embodiment, the deposition source may further include a connecting electrode that connects the first upper heater module and the second upper heater module and that is deformed together with a deformation of the upper heater module.

In an embodiment, the connecting electrode may have a curvature.

In an embodiment, the connecting electrode may include a plurality of metal sheets stacked in a third direction that crosses each of the first direction and the second direction. In an embodiment, the second electrode may include a third sub electrode and a fourth sub electrode. The third sub electrode may be connected to a first end of the upper heater module and the fourth sub electrode may be connected to a second end of the upper heater module, wherein the second end of the upper heater module is disposed opposite to the first end of the upper heater module. The third sub electrode and the fourth sub electrode may transmit power of a preset amount to the upper heater module.

In an embodiment, the lower heater module may include a first lower heater module and a second lower heater module. The first lower heater module and the second lower heater module may be spaced apart from each other in the first direction. The first electrode may include a first sub electrode and a second sub electrode. The first sub electrode may be connected to a first end of the first lower heater module and transmits first power to the first lower heater module. The second sub electrode may be connected to a first end of the second lower heater module and transmits second power to the first lower heater module.

In an embodiment, an amount of the first power and an amount of the second power may be different from each other.

In an embodiment, the deposition source may further include a connecting electrode that connects the first lower heater module and the second lower heater module and that is deformed together with a deformation of the lower heater module.

In an embodiment, the connecting electrode may have a curvature.

In an embodiment, the connecting electrode may include a plurality of metal sheets stacked in a third direction that crosses each of the first direction and the second direction.

In an embodiment, the deposition source may further include a first frame disposed inside the housing and to which the upper heater module and the lower heater module are fixed, a second frame disposed between the housing and the first frame, and a terminal block disposed between the housing and the second frame and electrically connected to the power supply.

In an embodiment, the terminal block may include a fixed end and a free end. The fixed end may be fixed to a bottom of the second frame and may be electrically connected to the power supply and the free end may be connected to the first electrode and may be movable in a third direction that crosses each of the first direction and the second direction.

In an embodiment, the deposition source may further include a connector disposed between the fixed end and the free end. The connector may include a plurality of metal sheets stacked in the third direction.

In an embodiment, the terminal block may include a fixed end and a free end. The fixed end may be fixed to a bottom of the second frame and may be electrically connected to the power supply and the free end may be connected to the second electrode and may be movable in a third direction that crosses each of the first direction and the second direction.

In an embodiment, the deposition source may further include a connector disposed between the fixed end and the free end. The connector may include a plurality of metal sheets stacked in the third direction.

Embodiments of a deposition source include a crucible that accommodates a deposition material, a plurality of nozzles disposed on the crucible and spaced apart from each other along a first direction, a housing accommodating the crucible and the plurality of nozzles, a plurality of lower heater modules disposed in an inner space of the housing and surrounding the crucible, an upper heater module disposed on the plurality of lower heater modules in the inner space of the housing, a power supply electrically connected to the plurality of lower heater modules and the upper heater module, and a controller that controls the power supply to apply a constant amount of power to the upper heater module.

In an embodiment, each of the plurality of lower heater modules and the upper heater module may be spaced apart by a predetermined distance.

In an embodiment, the plurality of lower heater modules may include a first lower heater module and a second lower heater module. The controller may control an amount of heat generated by each of the first lower heater module and the second lower heater module.

In an embodiment, an amount of heat generated by the upper heater module may be greater than the amount of heat generated by each of the plurality of lower heater modules.

As described above, according to embodiments, a deposition source may include a crucible that accommodates a deposition material, a plurality of nozzles disposed on the crucible and spaced apart from each other along a first direction, a housing accommodating the crucible and the plurality of nozzles, a lower heater module disposed in an inner space of the housing and surrounding the crucible, an upper heater module disposed on the lower heater module in the inner space of the housing, a first electrode extending in a second direction crossing the first direction and connected to the lower heater module, a second electrode extending in the second direction and connected to the upper heater module, and a power supply electrically connected to the first electrode and the second electrode. Accordingly, a temperature of each of the upper heater module and the plurality of lower heater modules may be controlled and film thickness distribution may be reduced or eliminated.

In addition, in an embodiment, the deposition source may further include a controller that controls the power supply to apply a constant amount of power to the upper heater module. Accordingly, a temperature difference between the plurality of nozzles included in the deposition source may be minimized.

In addition, in an embodiment, the deposition source may further include the connecting electrode connecting the plurality of upper heater modules to each other and/or the connecting electrode connecting the plurality of lower heater modules to each other. The connecting electrode may have a structure that alleviates thermal expansion stress. Accordingly, a lifespan of the heater modules included in the deposition source may be extended.

In addition, in an embodiment, the deposition source may further include the terminal block connected to each of the first electrode and the second electrode. The terminal block may include a fixed end and a free end. The fixed end may be electrically connected to the power supply and the free end may be a cantilever structure movable in the third direction. Accordingly, the lifespan of the heater modules included in the deposition source may be extended.

In addition, in an embodiment, the deposition source may further include a connector connecting the fixed end and the free end of the terminal block in the first direction. Accordingly, a size of a lower space of the deposition source may be minimized and a center of gravity of the deposition source may be lowered.

### BRIEF DESCRIPTION OF THE DRAWINGS

Illustrative, non-limiting embodiments will be more clearly understood from the following detailed description in conjunction with the accompanying drawings.

FIG. 1 is a cross-sectional view of a deposition apparatus, according to an embodiment.

FIG. 2 is a perspective view illustrating the deposition source included in the deposition apparatus of FIG. 1, according to an embodiment.

FIG. 3 is a cross-sectional view taken along line I-I′ of FIG. 2, according to an embodiment.

FIG. 4 is a block diagram illustrating a controller included in the deposition source of FIG. 3, according to an embodiment.

FIG. 5 is a block diagram illustrating a controller included in the deposition source of FIG. 3, according to an embodiment.

FIG. 6 is a perspective view illustrating a plurality of heater modules included in the deposition source of FIG. 3, according to an embodiment.

FIG. 7 is a side view illustrating electrodes connected to the plurality of heater modules of FIG. 6, according to an embodiment.

FIG. 8 is an enlarged view illustrating area A of FIG. 7, according to an embodiment.

FIG. 9 is an enlarged view illustrating area B of FIG. 7, according to an embodiment.

FIG. 10 is an enlarged view illustrating area C of FIG. 9, according to an embodiment.

FIG. 11 is an enlarged view illustrating area C of FIG. 9, according to an embodiment.

FIG. 12 is a front view illustrating a first connecting electrode of FIG. 7, according to a first embodiment.

FIG. 13 is a front view illustrating a first connecting electrode of FIG. 7, according to a first embodiment.

FIG. 14 is a front view illustrating a first connecting electrode of FIG. 7, according to a second embodiment.

FIG. 15 is a front view illustrating a first connecting electrode of FIG. 7, according to a second embodiment.

FIG. 16 is a front view illustrating a first connecting electrode of FIG. 7, according to a third embodiment.

FIG. 17 is a front view illustrating a first connecting electrode of FIG. 7, according to a third embodiment.

FIG. 18 is a front view illustrating a second connecting electrode, according to a first embodiment of FIG. 7.

FIG. 19 is a front view illustrating a second connecting electrode, according to a second embodiment of FIG. 7.

FIG. 20 is a front view illustrating a second connecting electrode, according to a third embodiment of FIG. 7.

FIG. 21 is an enlarged view illustrating the second connector of FIG. 7, according to an embodiment.

FIG. 22 is an enlarged view illustrating the second connector of FIG. 7, according to an embodiment.

FIG. 23 is a cross-sectional view illustrating a pixel formed by a deposition process using the deposition apparatus including the deposition source, according to an embodiment.

### DETAILED DESCRIPTION

The invention now will be described more fully hereinafter with reference to the accompanying drawings, in which various embodiments are shown. The invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” includes all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

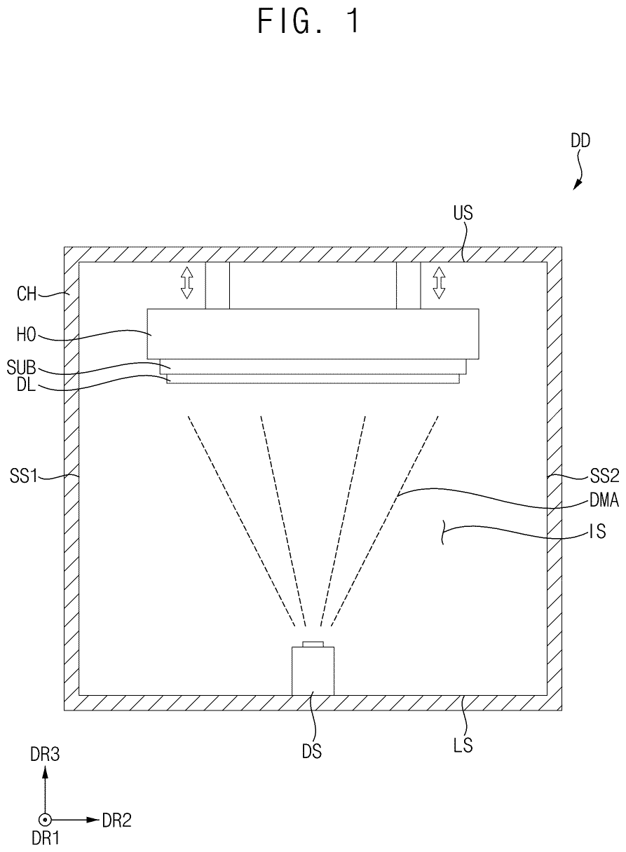

FIG. 1 is a cross-sectional view of a deposition apparatus, according to an embodiment.

In an embodiment and referring to FIG. 1, the deposition apparatus DD may include a deposition chamber CH, a substrate holder HO, and a deposition source DS.

In an embodiment, the deposition chamber CH may provide an internal space IS in which a deposition process is performed. The deposition chamber CH may be connected to a vacuum pump. The vacuum pump may control an internal pressure of the deposition chamber CH. In addition, the vacuum pump may discharge a remaining amount of deposition material DMA, which will be described later, to an outside of the deposition chamber CH.

In an embodiment, the deposition chamber CH may include a plurality of sides. For example, the deposition chamber CH may include an upper surface US, a lower surface LS, and a plurality of side surfaces (e.g., a first side SS1 and a second side SS2).

For example, in an embodiment, the upper surface US and the lower surface LS may each be defined by a first direction DR1 and a second direction DR2. The second direction DR2 may cross the first direction DR1. For example, the lower surface LS may face the upper surface US in a third direction DR3. The third direction DR3 may cross the first direction DR1. In addition, the third direction DR3 may also cross the second direction DR2. The third direction DR3 may be defined as a direction opposite to a direction of gravity.

In an embodiment, the plurality of side surfaces may cross each of the upper surface US and the lower surface LS. Specifically, the plurality of side surfaces may be perpendicular to each of the upper surface US and the lower surface LS.

In an embodiment, the plurality of side surfaces may include a first side SS1, a second side SS2, a third side, and a fourth side. The first side SS1 and the second side SS2 may face each other in the second direction DR2. Although not shown in FIG. 1, the third side and the fourth side may face each other in the first direction DR1.

In an embodiment, each of the first side SS1 and the second side SS2 may be defined by the first direction DR1 and the third direction DR3. Each of the third side and the fourth side may be defined by the second direction DR2 and the third direction DR3.

In an embodiment, the substrate holder HO and the deposition source DS may be disposed in the deposition chamber CH. For example, the substrate holder HO and the deposition source DS may be arranged to face each other.

As an example, in an embodiment, the deposition apparatus DD may be a horizontal deposition apparatus. In this embodiment, the substrate holder HO may be disposed on the upper surface US of the deposition chamber CH, and the deposition source DS may be disposed on the lower surface LS. In other words, the substrate holder HO and the deposition source DS may face each other in the third direction DR3. Alternatively, the substrate holder HO may be disposed on the lower surface LS of the deposition chamber CH, and the deposition source DS may be disposed on the upper surface US.

As another example, in an embodiment, the deposition apparatus DD may be a vertical deposition apparatus. Although not shown in the FIG., the substrate holder HO may be disposed on the first side SS1 of the deposition chamber CH, and the deposition source DS may be disposed on the second side SS2. In other words, the substrate holder HO and the deposition source DS may face each other in the second direction DR2. Alternatively, the substrate holder HO may be disposed on the third side of the deposition chamber CH, and the deposition source DS may be disposed on the fourth side. In other words, the substrate holder HO and the deposition source DS may face each other in the first direction DR1.

In an embodiment, a substrate SUB may be fixed to one surface of the deposition chamber CH (e.g., the upper surface US of the deposition chamber CH) by the substrate holder HO. Accordingly, the substrate SUB may be prevented from moving while the deposition process is performed. For example, the substrate holder HO may be an electrostatic chuck. For example, an area of the electrostatic chuck may be larger than an area of the substrate SUB. Accordingly, the substrate SUB may be stably fixed to the upper surface US of the deposition chamber CH by the electrostatic chuck.

However, the invention is not limited thereto. For example, in an embodiment, the deposition chamber CH may have various shapes to perform the deposition process. For example, the deposition chamber CH may have various shapes, such as a circular or polygonal shape.

In an embodiment, the deposition material DMA may be stored in the deposition source DS. When the deposition source DS is heated, the deposition material DMA may be vaporized. The vaporized deposition material DMA may be deposited onto the substrate SUB. Accordingly, a deposition film DL may be formed on the substrate SUB.

In an embodiment, the deposition material DMA may include a material that may be vaporized by heat. For example, the deposition material DMA may include metal. As another example, the deposition material DMA may include an inorganic material.

Hereinafter, the deposition source DS with improved thickness uniformity will be described in detail, according to an embodiment.

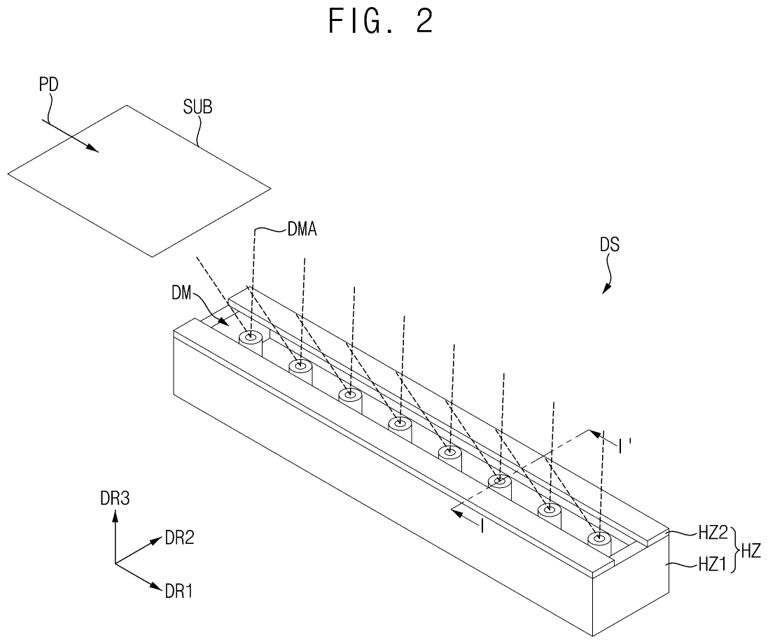

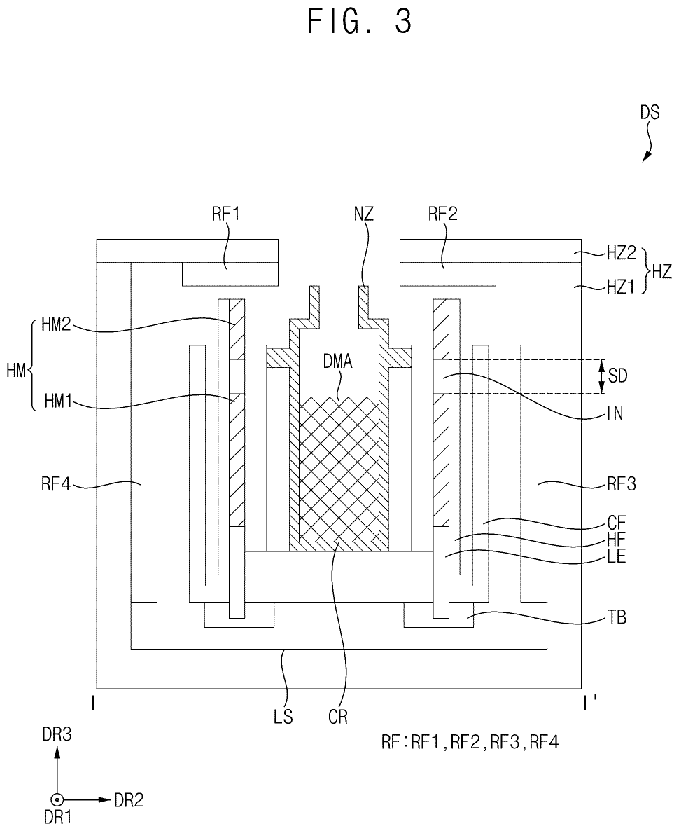

FIG. 2 is a perspective view illustrating the deposition source included in the deposition apparatus of FIG. 1, according to an embodiment. FIG. 3 is a cross-sectional view taken along line I-I′ of FIG. 2, according to an embodiment.

In an embodiment and referring to FIGS. 2 and 3, the deposition source DS may include a housing HZ, a deposition module DM disposed within the housing HZ, and a reflector RF. The deposition module DM may include a first frame HF, a second frame CF, a crucible CR, a nozzle NZ, a heater module HM, a lower electrode LE, and a terminal block TB.

In an embodiment, the deposition source DS may be the linear deposition source. The linear deposition source may include the deposition module DM extending in one direction (e.g., the first direction DR1). The substrate SUB may be disposed on the deposition source DS. The deposition material DMA vaporized (or sublimated) from the deposition module DM may form the deposition film (e.g., the deposition film DL of FIG. 1) on the substrate SUB.

For example, in an embodiment, while the deposition source DS is fixed, only the substrate SUB may be moved. For example, the substrate SUB may rotate or move linearly within the deposition chamber CH.

However, the invention is not limited thereto. For example, in an embodiment, only the deposition source DS may be moved while the substrate SUB is fixed.

In an embodiment, the housing HZ may include a main body HZ1 and a top plate HZ2.

In an embodiment, the main body HZ1 may accommodate the deposition module (DM). For example, the main body HZ1 may have a rectangular shape with a hollow interior. An upper portion of the main body HZ1 may be open. For example, a portion of the nozzle included in the deposition module DM (e.g., a portion of the nozzle NZ of FIG. 3) may be exposed to an outside of the housing HZ. Accordingly, the deposition material DMA may be discharged in the third direction DR3.

In an embodiment, the top plate HZ2 may be disposed on the main body HZ1. For example, in one embodiment, the top plate HZ2 may include two top plates that may be arranged to be spaced apart from each other at a predetermined distance in the second direction DR2. As the top plate HZ2 is arranged to have the predetermined distance, the portion of the nozzle may be exposed to the outside via the opening located between the two top plates HZ2. In another embodiment, the top plate HZ2 may cover the entire upper portion of the main body HZ1. In this case, an opening may be formed in the top plate HZ2 to expose the portion of the nozzle to the outside.

However, the invention is not limited thereto. In an embodiment, the top plate HZ2 may be omitted, or the main body HZ1 and the top plate HZ2 may be formed integrally.

In an embodiment, the deposition module DM may provide the deposition material DMA to the substrate SUB. The deposition material DMA may be discharged from the nozzle included in the deposition module DM. The deposition material DMA may be simultaneously discharged from the plurality of nozzles to uniformly provide the deposition material DMA to each position of the substrate SUB. Accordingly, the thickness uniformity of the deposition film DL may be improved more than that of the deposition film formed using a deposition apparatus including a point-type deposition source.

In an embodiment, the first frame HF may be disposed inside the housing HZ. Specifically, the first frame HF may be disposed between the housing HZ and the crucible CR. For example, the first frame HF may surround the sides and the bottom of the crucible CR.

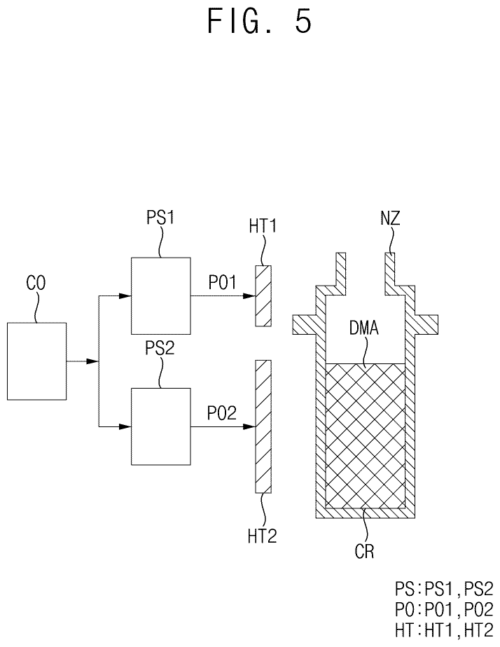

In an embodiment, the first frame HF may have a rectangular shape with an open top and a hollow interior. The heater module HM may be fixed to the first frame HF. At this time, the heater module HM may be divided into a horizontal direction (e.g., the first direction DR1) and a vertical direction (e.g., the third direction DR3). A detailed description of the arrangement of the heater module HM will be described later with reference to FIG. 5 and hereinbelow.

In an embodiment, the second frame CF may be disposed between the first frame HF and the housing HZ. For example, the second frame CF may surround the sides of the first frame HF.

In an embodiment, the second frame CF may cool the heat radiated toward a top of the deposition source. In addition, the second frame CF may reduce the amount of heat generated by the substrate that is disposed on the deposition source. Accordingly, damage to the substrate due to high temperature may be prevented.

In an embodiment, the second frame CF may include a cooling pipe and a cooling bracket that covers an outer surface of the cooling pipe. Refrigerant or coolant may circulate inside the cooling pipe.

In an embodiment, the crucible CR may accommodate the deposition material DMA. For example, as shown in FIG. 2, the crucible CR may be a linear crucible extending in the first direction DR1. The linear crucible may have a larger capacity of the deposition material DMA than the point-type crucible included in a point-type deposition source. Accordingly, the linear deposition source may have a longer time to perform the deposition process than the point-type deposition source.

In an embodiment, the crucible CR may include a heat-resistant material. For example, the crucible CR may include metal, alloy, ceramic, glass, graphite, carbon composition, or the like. As another example, the crucible CR may include molybdenum lanthanum (Mo—La), tungsten (W), titanium-zirconium-molybdenum alloy (TZM), tantalum (Ta), or the like. These may be used alone or in combination with each other. However, the invention is not limited thereto. For example, the crucible CR may include various heat-resistant materials.

In an embodiment, the nozzles NZ may be plural. In an embodiment, the plurality of nozzles NZ may be arranged to be spaced apart from each other in one direction (e.g., the first direction DR1). For example, the plurality of nozzles NZ may be arranged at equal intervals. As another example, the plurality of nozzles NZ may be arranged to have different intervals from each other. The plurality of nozzles NZ may discharge the deposition material DMA toward the third direction DR3.

In an embodiment, the nozzle NZ may include a heat-resistant material. In one embodiment, the nozzle NZ may include metal, alloy, ceramic, glass, graphite, carbon composition, or the like. In another embodiment, the nozzle NZ may include molybdenum lanthanum (Mo—La), tungsten (W), titanium-zirconium-molybdenum alloy (TZM), tantalum (Ta), or the like. These may be used alone or in combination with each other. However, the invention is not limited thereto. For example, the nozzle NZ may include various heat-resistant materials.

In an embodiment, the heater module HM may heat the crucible CR and/or the nozzle NZ. For example, the heater module HM may heat the crucible CR and/or the nozzle NZ to about 100 degrees or more.

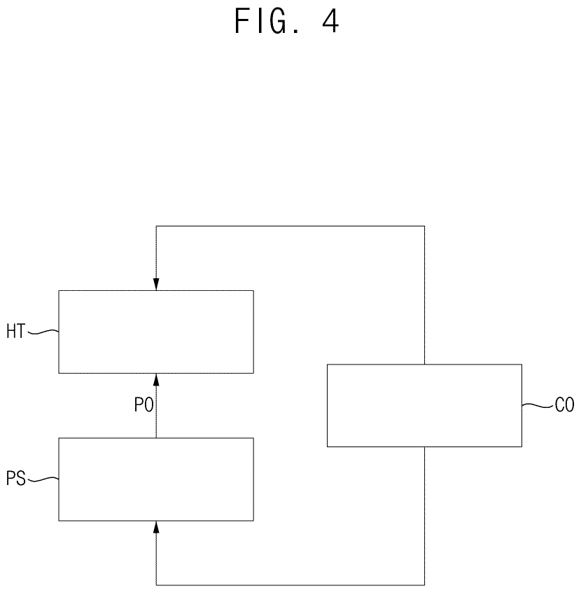

In an embodiment, the heater module HM may be fixed to the first frame HF. The heater module HM may include an upper heater module HM1 and a lower heater module HM2. For example, the upper heater module HM1 may be disposed adjacent to the nozzle NZ. Accordingly, the upper heater module HM1 may heat the nozzle NZ. The lower heater module HM2 may be disposed adjacent to the crucible CR. Accordingly, the lower heater module HM2 may heat the crucible CR. In other words, the heater module HM may control temperatures of the crucible CR and the nozzle NZ differently as it is divided into upper and lower parts. A detailed description of the heater module HM will be described later with reference to FIG. 4 and hereinbelow.

In an embodiment, the lower electrode LE may pass through the lower surface LS of the housing HZ and be exposed to the outside. The lower electrode LE may be connected to the heater module HM. Specifically, the lower electrode LE may be connected to a heating element included in the heater module HM. The lower electrode LE may be connected to an end of the heater module HM to transmit power to the heater module HM. In an embodiment, the lower electrode LE may be connected to each of the upper heater module HM1 and the lower heater module HM2.

In an embodiment, the lower electrode LE may include a metal material. For example, the lower electrode LE may include silver (Ag), copper (Cu), nickel (Ni), or the like. These may be used alone or in combination with each other. However, the invention is not limited thereto. For example, the lower electrode LE may include various conductive materials.

In an embodiment, the lower electrode LE may be covered with an insulator. For example, the insulator may surround the lower electrode LE. Accordingly, the insulator may insulate the lower electrode LE and the first frame HF. For example, the insulator may include boron nitride (BN), pyrolytic boron nitride (PBM), aluminum nitride (ALN), or the like. These may be used alone or in combination with each other. However, the invention is not limited thereto.

In an embodiment, the terminal block TB may be disposed between the housing HZ and the second frame CF. For example, the terminal block TB may be disposed between a bottom surface of the second frame CF and a bottom surface of the housing HZ. For example, the terminal block TB may be fixed to the bottom surface of the second frame CF.

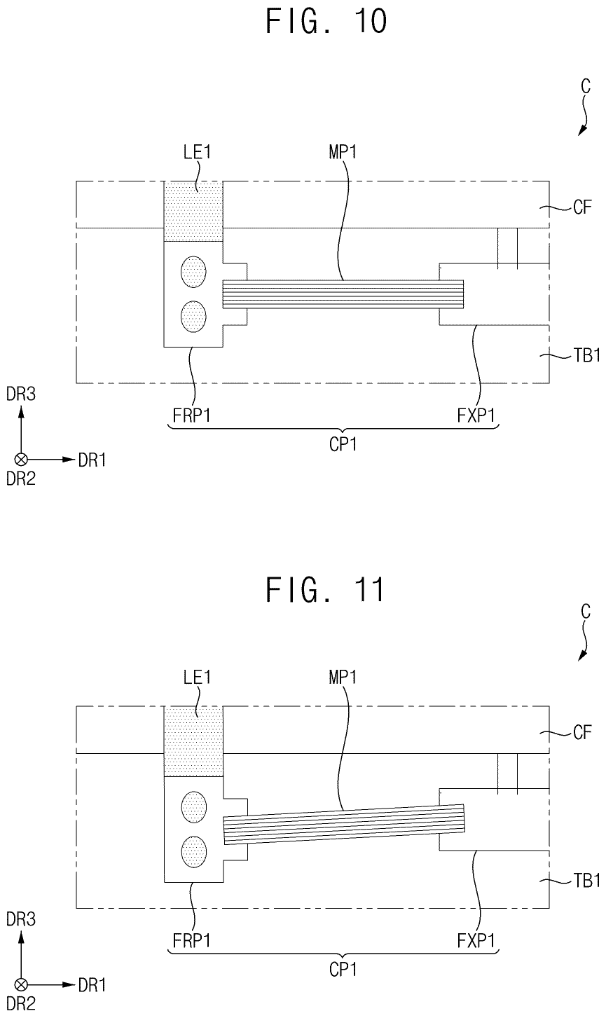

In an embodiment, the lower electrode LE may be electrically connected to a power supply PS in the terminal block TB. A detailed description of this will be provided later with reference to FIGS. 10 and 11.

In an embodiment, as the deposition source DS includes the terminal block TB, a size of the lower space of the deposition source DS may be reduced compared to a structure in which the lower electrode LE is arranged vertically, and a center of gravity may be lowered, and a flow amount of the deposition material DMA may be reduced. Accordingly, the deposition process may be performed stably.

In an embodiment, the reflector RF may be disposed on an inner side of the housing HZ. The reflector RF may reflect radiant heat emitted from the heater module HM. That is, the reflector RF may improve a radiation efficiency of the heater module HM by suppressing waste of radiant heat.

In an embodiment, the reflector RF may include metal. For example, the reflector RF may include Mo (molybdenum), Ta (tantalum), W (tungsten), Al (aluminum), Au (gold), Ag (silver), Mn (manganese), Ti (titanium), ZrO₂ (zirconia), Al₂O₃ (alumina), TiO₂ (titanium dioxide), BN (boron nitride), PBM (pyrolytic boron nitride), ALN (aluminum nitride), SUS (steel use stainless), or the like. These may be used alone or in combination with each other. However, the invention is not limited thereto. For example, the reflector RF may include various metals.

In an embodiment, the reflector RF may have undergone surface treatment such as polishing to reduce thermal emissivity.

In the embodiment shown in FIG. 3, the reflector RF is described as being coupled to the inner side of the housing HZ and spaced apart from the first frame HF, however, the invention is not limited thereto. For example, the reflector RF may be coupled to the first frame HF and may be spaced apart from the housing HZ.

FIGS. 4 and 5 are views illustrating a controller included in the deposition source of FIG. 3, according to an embodiment.

In an embodiment and referring to FIGS. 1, 3, 4, and 5, the deposition source DS may include a heater HT, the power supply PS, and a controller CO.

In an embodiment, the heater module HM may include the heater HT and an insulator.

In an embodiment, the heater HT may receive power to generate the heat and emit the radiant heat to the outside.

For example, in an embodiment, the heater HT may be a heating wire. The heating wire may have different width or length depending on its location. Accordingly, the heater HT may have different resistance values depending on its location.

For example, in an embodiment, the heater HT may include ceramic particles. The ceramic particles may increase heat capacity. For example, the ceramic particles may include glass particles, silicon particles, or the like. However, the invention is not limited thereto.

For example, in an embodiment, the heater HT may be covered by the insulator. The insulator may prevent foreign substances from damaging the heater HT. In addition, the insulator may block (insulate) electrical connections that may occur between neighboring heaters HT.

For example, in an embodiment, the insulator may be plate-shaped. Accordingly, the insulator may insulate the heater module HM and the first frame HF. For example, the insulator may include boron nitride (BN), pyrolytic boron nitride (PBM), aluminum nitride (ALN), or the like. These may be used alone or in combination with each other. However, the invention is not limited thereto.

In an embodiment, the power supply PS may supply power PO to the heater HT. A temperature of the heater HT may vary depending on a size of the power PO. The amount of vaporization (or amount of sublimation) of the deposition material (e.g., the deposition material DMA of FIG. 1) may vary depending on the temperature of the heater HT.

For example, in an embodiment, the larger the power supply PO, the higher the temperature of the heater HT may be. As the temperature of the heater HT increases, the amount of vaporization (or amount of sublimation) of the deposition material may increase. To this end, the power supply PS may supply voltages of various sizes to the heater HT.

For example, in an embodiment, the power supply PS may include a lead acid battery, a secondary battery, a super capacitor, and/or the like. However, the invention is not limited thereto.

In an embodiment, the controller CO may control operations of various components included in the deposition apparatus DD of FIG. 1. For example, the controller CO may be a microprocessor. However, the invention is not limited thereto.

In an embodiment, the controller CO may control the operation of the heater HT. For example, the controller CO may control operations such as turning the heater HT on, off, increasing the temperature, lowering the temperature, maintaining the temperature, and/or the like.

In an embodiment, the deposition apparatus DD may include the plurality of heaters HT, the plurality of power supplies PS, and the controller CO. For example, the plurality of heaters HT may include a first heater HT1 and a second heater HT2. The plurality of power supplies PS may include a first power supply PS1 and a second power supply PS2. The upper heater module HM1 may be connected to the first power supply PS1, and the lower heater module HM2 may be connected to the second power supply PS2.

In an embodiment, the controller CO may control each of the plurality of heater modules HM. For example, the controller CO may control each of the first power supply PS1 and the second power supply PS2. The first power supply PS1 may transmit first power PO1 to the first heater HT1. The second power supply PS2 may transmit second power PO2 to the second heater HT2.

In an embodiment, the upper heater module HM1 may be disposed adjacent to the nozzle NZ. Accordingly, the upper heater module HM1 may heat the nozzle NZ. Specifically, the controller CO may control the first power supply PS1. The first power supply PS1 may adjust the amount of the first power PO1 applied to the first heater HT1. The first heater HT1 may control the amount of heat generated to the nozzle NZ and control the temperature of the nozzle NZ. Accordingly, the temperature of the nozzle NZ may be maintained constant.

In an embodiment, the lower heater module HM2 may be disposed adjacent to the crucible CR. Accordingly, the lower heater module HM2 may heat the crucible CR. Specifically, the controller CO may control the second power supply PS2. The second power supply PS2 may adjust the amount of the second power PO2 applied to the second heater HT2. The second heater HT2 may control the amount of heat generated to the crucible CR and control the temperature of the crucible CR. Accordingly, the vaporization amount (or sublimation amount) of the deposition material DMA accommodated in the crucible CR may be adjusted. In an embodiment, the amount of heat generated by the upper heater module HM1 may be greater than that of the lower heater module HM2.

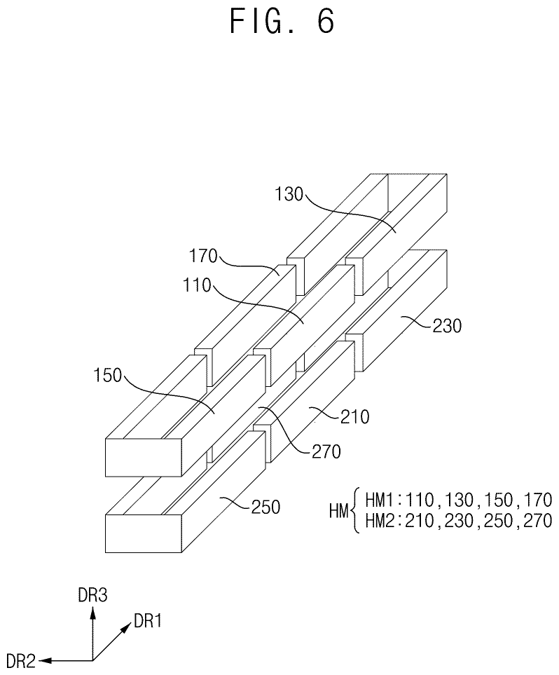

FIG. 6 is a perspective view illustrating a plurality of heater modules included in the deposition source of FIG. 3, according to an embodiment.

In an embodiment and referring to FIGS. 3 and 6, the deposition source DS may include the plurality of heater modules HM. In an embodiment, the plurality of heater modules HM may be disposed in the inner space of the housing HZ. The plurality of heater modules HM may be fixed to the first frame HF.

In an embodiment, the heater module HM may include the upper heater module HM1 and the lower heater module HM2. The upper heater module HM1 may be disposed on the lower heater module HM2.

In an embodiment, the upper heater module HM1 and the lower heater module HM2 may be arranged to be spaced apart from each other in the third direction DR3. In other words, the upper heater module HM1 and the lower heater module HM2 may be arranged to be spaced apart from each other at a predetermined distance SD. The predetermined distance SD may change depending on the temperature of the heater module HM.

For example, in an embodiment, the upper heater module HM1 may include a first upper heater module 110, a second upper heater module 130, a third upper heater module 150, and a fourth upper heater module 170. Each of the first upper heater module 110, the second upper heater module 130, the third upper heater module 150, and the fourth upper heater module 170 may be spaced apart from each other in the first direction DR1 and/or the second direction DR2.

For example, in an embodiment, the lower heater module HM2 may include a first lower heater module 210, a second lower heater module 230, a third lower heater module 250, and a fourth lower heater module 270. Each of the first lower heater module 210, the second lower heater module 230, the third lower heater module 250, and the fourth lower heater module 270 may be spaced apart from each other in the first direction DR1 and/or the second direction DR2.

In an embodiment, as the upper heater module HM1 and/or the lower heater module HM2 are divided and arranged, the temperature may be set differently for each section. Accordingly, the evaporation rate of the deposition material DMA for each section may be maintained more precisely.

In an embodiment, the heater module HM may have various forms. For example, the heater module HM may have a plate shape (e.g., a shape of the first upper heater module 110 and a fourth upper heater module 170). For another example, the heater module (HM) may have a two-tine fork (‘⊏’) shape (e.g., a shape of the second upper heater module 130 and the third upper heater module 150). However, the present invention is not limited thereto.

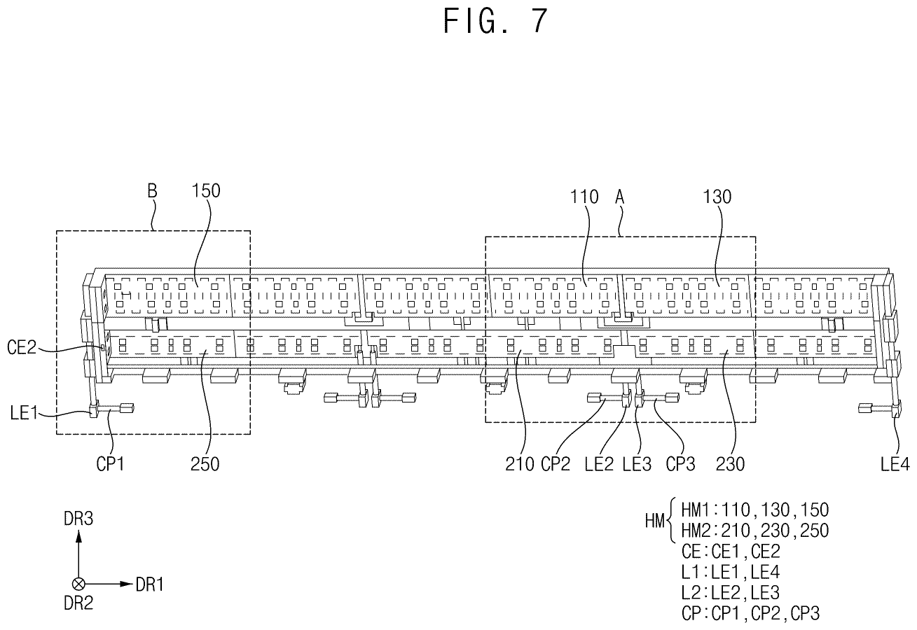

FIG. 7 is a side view illustrating electrodes connected to the plurality of heater modules of FIG. 6, according to an embodiment.

In an embodiment and referring to FIGS. 5 and 7, the deposition source DS may include an electrode (e.g., a first electrode L1, a second electrode L2, or a connecting electrode CE). connected to each of the plurality of heater modules HM. The first electrode L1 and the second electrode L2 of FIG. 7 may correspond to the lower electrode LE of FIG. 3.

In an embodiment, the plurality of upper heater modules HM1 may be plural. For example, the upper heater module HM1 may include the first upper heater module 110, the second upper heater module 130, and the third upper heater module 150. The second upper heater module 130 may be disposed adjacent to the first upper heater module 110 in the first direction DR1. The third upper heater module 150 may be disposed adjacent to the first upper heater module 110 in a direction opposite to the first direction DR1.

In an embodiment, the plurality of lower heater modules HM2 may be plural. For example, the lower heater module HM2 may include the first lower heater module 210, the second lower heater module 230, and the third lower heater module 250. The second lower heater module 230 may be disposed adjacent to the first lower heater module 210 in the first direction DR1. The third lower heater module 250 may be disposed adjacent to the first lower heater module 210 in a direction opposite to the first direction DR1.

In an embodiment, the upper heater module HM1 and the lower heater module HM2 may be spaced apart from each other in the third direction DR3. As shown in FIG. 3, the upper heater module HM1 and the lower heater module HM2 may be spaced apart from each other to have the predetermined distance SD.

In an embodiment, the connecting electrode CE may be further disposed to connect the heater module HM in series. For example, the second connecting electrode CE2 is disposed to connect the first lower heater module 210 and the second upper heater module 130 between the first lower heater module 210 and the second upper heater module 130. The second connecting electrode CE2 connecting the plate-shaped heater modules may be disposed so that the third lower heater module 250 has the two-tine fork (‘⊏’) shape.

In an embodiment, the first electrode L1 may be connected to the upper heater module HM1. The first electrode L1 may extend in the third direction DR3.

In an embodiment, the first electrode L1 may include a first sub-electrode LE1 and a fourth sub-electrode LE4. In an embodiment, the first sub-electrode LE1 may be connected to a first end of the upper heater module HM1, and the fourth sub-electrode LE4 is connected to a second end of the upper heater module HM1. The second end may face the first end in the first direction DR1.

In an embodiment, the controller CO may operate the power supply PS (e.g., the first power PO1 of FIG. 5) to apply power having a constant amount to the plurality of upper heater modules HM1. For example, the first electrode L1 may transmit the first power PO1 of a preset amount to the upper heater module HM1. Accordingly, the temperature of the nozzle NZ may be maintained constant while the deposition process proceeds.

In an embodiment, when the temperature of the nozzle NZ is less than a predetermined range, the deposition material DMA may solidify in the nozzle NZ. Accordingly, clogging of the nozzle NZ may occur.

On the other hand, in an embodiment, when the temperature of the nozzle NZ is greater than the predetermined range, the deposition material DMA may leak between the nozzle NZ and the crucible CR. Accordingly, the deposition apparatus (e.g., the deposition apparatus DD of FIG. 1) may be contaminated, the amount of material consumed may increase, and the material efficiency may be reduced.

As the deposition source DS, according to embodiment, maintains a constant temperature of the nozzle NZ, the clogging of the nozzle NZ, the contamination of the deposition apparatus, and reduction of the material efficiency may be prevented.

In an embodiment, the second electrode L2 may be connected to the lower heater module HM2. The second electrode L2 may extend in the third direction DR3.

In an embodiment, the second electrode L2 may include a second sub-electrode LE2 and a third sub-electrode LE3. In an embodiment, the second sub-electrode LE2 may be connected to one end of the first lower heater module 210, and the third sub-electrode LE3 may be connected to the second lower heater module 230.

In an embodiment, the controller CO may control the power supply PS to control the heat generation amount (or temperature) of each of the plurality of lower heater modules HM2. For example, the second sub electrode LE2 may transmit the first power to the first lower heater module 210, and the third sub-electrode LE3 may transmit the second power to the second lower heater module 230.

In an embodiment, the amount of the first power and the amount of the second power may be different from each other. In this case, the amount of heat generated by the first lower heater module 210 and the amount of heat generated by the second lower heater module 230 may be different from each other.

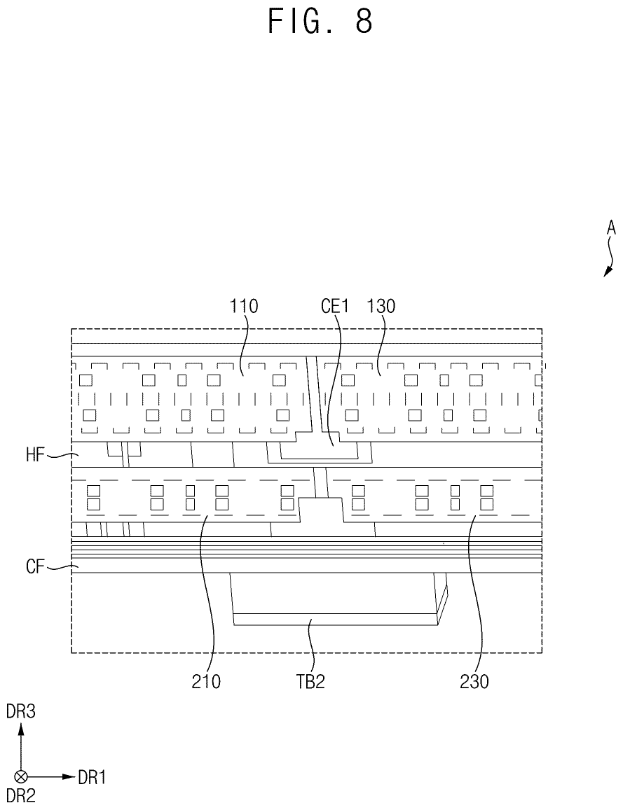

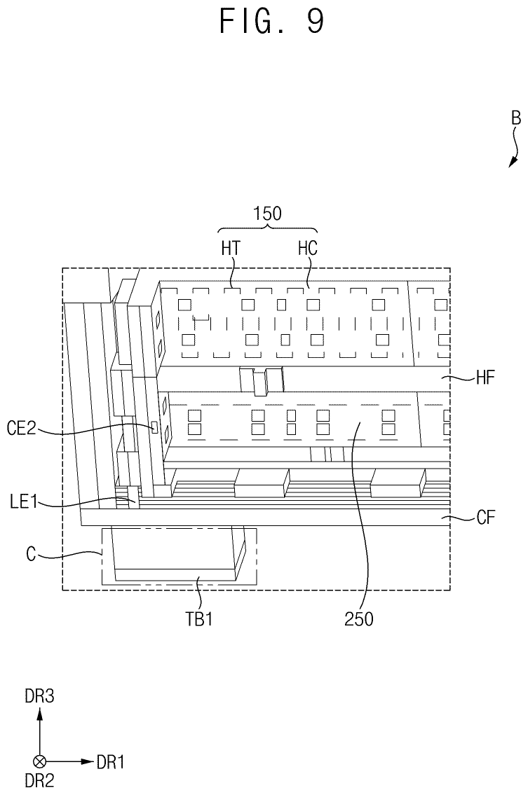

FIG. 8 is an enlarged view illustrating area A of FIG. 7, according to an embodiment. FIG. 9 is an enlarged view illustrating area B of FIG. 7, according to an embodiment.

Referring to FIGS. 3, 5, 7, 8, and 9, in an embodiment, the heater module HM may include the heater HT and a heater cover HC. Referring to FIGS. 3, 4, and 5, the heater cover HC may cover the heater HT. For example, in an embodiment, the heater cover HC may include an insulating material. Accordingly, the heater cover HC may prevent insulation breakdown caused by the deposition material DMA. In addition, the heater cover HC may insulate the heater HT and the first frame HF.

In an embodiment, the plurality of heater modules HM may be fixed to the first frame HF, and the first frame HF may be surrounded by the second frame CF. For example, the upper heater module HM1 and the lower heater module HM2 may be fixed to the first frame HF to be spaced apart from each other in the third direction DR3. The first upper heater module 110 and the second upper heater module 130 may be fixed to the first frame HF to be spaced apart from each other in the first direction DR1. The first lower heater module 210 and the second lower heater module 230 may be fixed to the first frame HF to be spaced apart from each other in the first direction DR1.

In an embodiment, the terminal block TB may be fixed to the second frame CF. There may be a plurality of terminal blocks TB. For example, the terminal block TB may include a first terminal block TB1 and a second terminal block TB2. The first sub electrode LE1 may be connected to the first terminal block TB1. The second sub electrode LE2 may be connected to the second terminal block TB2.

FIGS. 10 and 11 are views illustrating area C of FIG. 9, according to an embodiment.

For example, in an embodiment, FIGS. 10 and 11 are views illustrating a first connector CP1 of FIG. 7.

Referring to FIGS. 3, 5, 7, 9, 10, and 11, in an embodiment, the first terminal block TB1 may be fixed to the second frame CF.

In an embodiment, the first terminal block TB1 may include a first fixed end FXP1 and a first free end FRP1. The first fixed end FXP1 is fixed to a bottom surface of the second frame CF and may be electrically connected to the power supply PS. The first free end FRP1 may be connected to the first sub electrode LE1, and the first free end FRP1 may move in the third direction DR3. In other words, the first sub electrode LE1 may be fixed to the first terminal block TB1 in a cantilever format.

In an embodiment, the first fixed end FXP1 may be connected to the power supply PS so that the power PO may be applied. The first free end FRP1 may move in the vertical direction. When the heater module HM expands due to heat, stress may be generated in a longitudinal direction (e.g., the third direction DR3) of the first electrode L1. In this case, the damage to the heater HT may occur due to a stress accumulation. The deposition source DS according to embodiments may relieve the thermal expansion stress by fixing the first electrode L1 in the cantilever format.

In an embodiment, the first fixed end FXP1 and the first free end FRP1 may be connected through the first connector CP1. Accordingly, the power PO provided from the power supply PS may be transmitted to the heater module HM.

In an embodiment, the first connector CP1 may include the plurality of metal sheets MP1 stacked in the third direction DR3. Accordingly, the thermal expansion stress may be relieved.

However, the invention is not limited thereto. For example, the first electrode L1 and the first connector CP1 may have various shapes that may alleviate the thermal expansion stress. Because of this, the lifespan of the heater module HM may be extended.

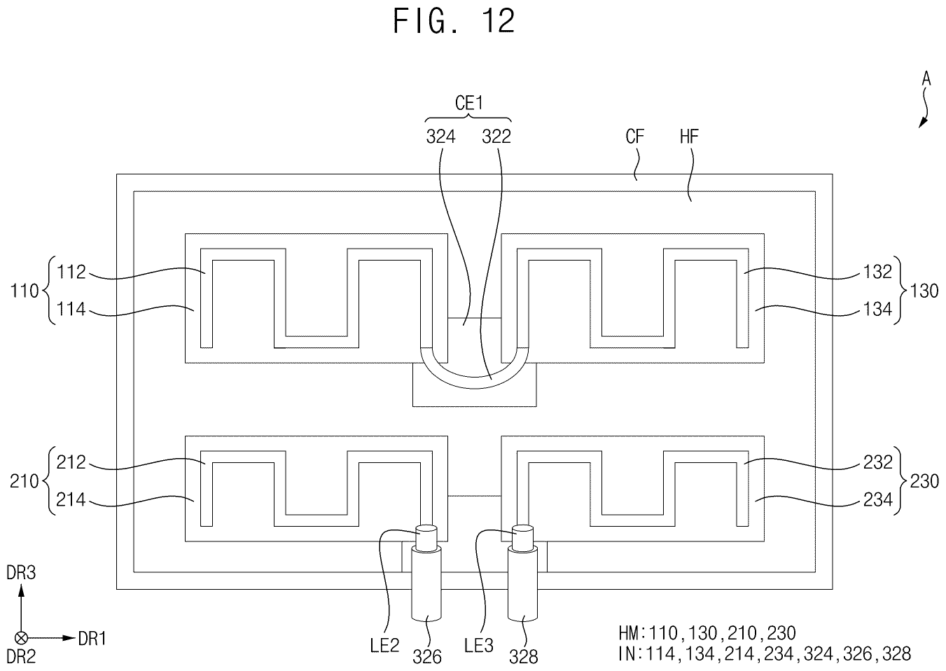

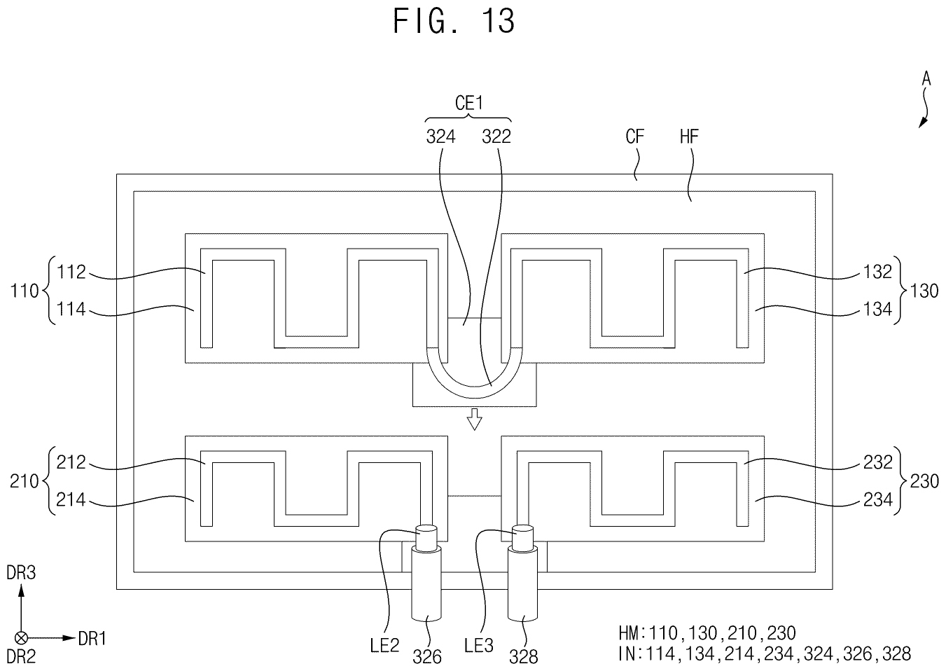

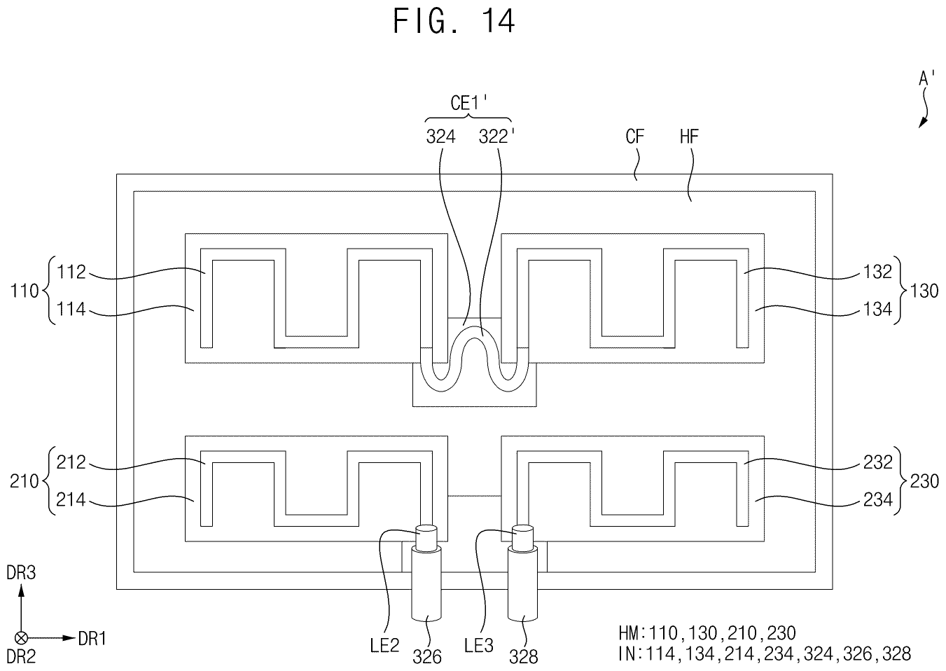

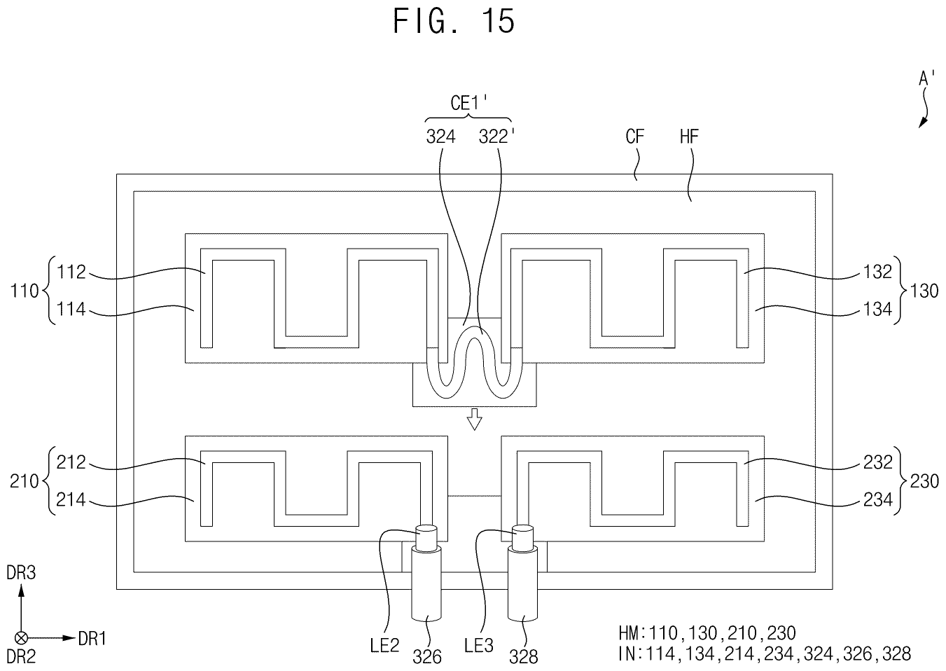

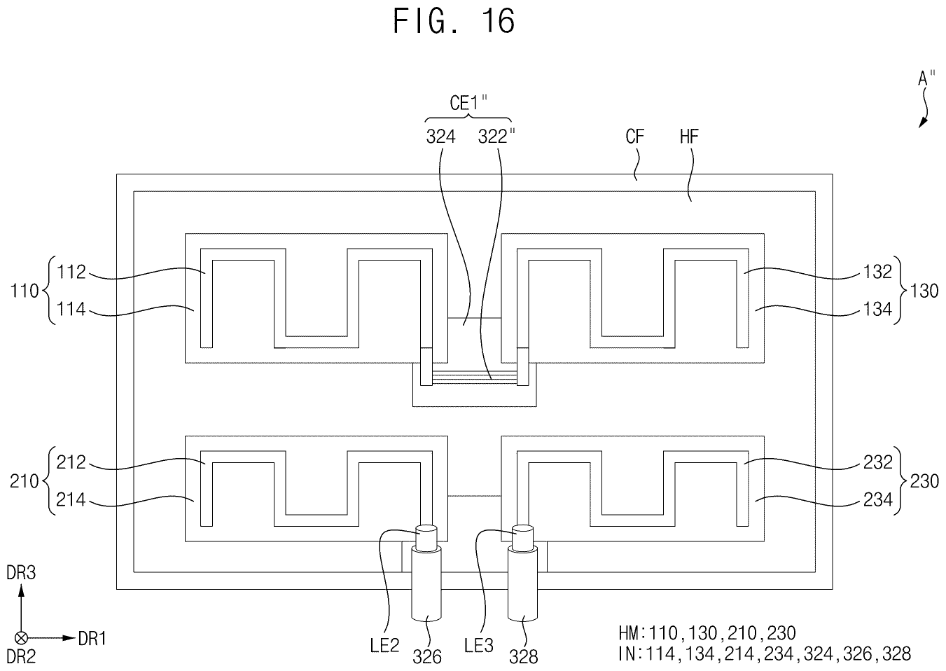

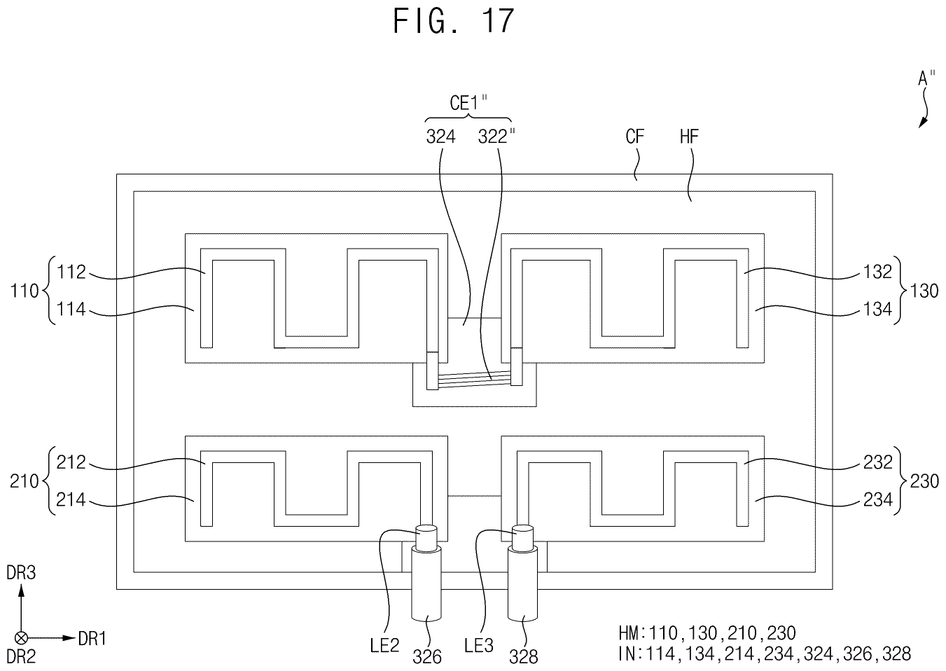

FIGS. 12 and 13 are front views illustrating a first connecting electrode of FIG. 7, according to a first embodiment. FIGS. 14 and 15 are front views illustrating a first connecting electrode of FIG. 7, according to a second embodiment. FIGS. 16 and 17 are front views illustrating a first connecting electrode of FIG. 7, according to a third embodiment.

In an embodiment and referring to FIGS. 3, 7, 12, and 13, the plurality of heater modules HM may include the plurality of heaters and an insulator IN. The insulator IN may cover the plurality of heater modules HM and the plurality of electrodes.

For example, in an embodiment, the plurality of heater modules HM may include the first upper heater module 110, the second upper heater module 130, the first lower heater module 210, and the second lower heater module 230.

In an embodiment, the first upper heater module 110 may include a first heater 112 and a first insulator 114. The first insulator 114 may cover the first heater 112. The second upper heater module 130 may include a second heater 132 and a second insulator 134. The second insulator 134 may cover the second heater 132. The first lower heater module 210 may include a third heater 212 and a third insulator 214. The third insulator 214 may cover the third heater 212. The second lower heater module 230 may include a fourth heater 232 and a fourth insulator 234. The fourth insulator 234 may cover the fourth heater 232.

In an embodiment, the first upper heater module 110 and the second upper heater module 130 may be connected in series by the first connecting electrode CE1. The first connecting electrode CE1 may include a first sub connecting electrode 322 and a fifth insulator 324. The fifth insulator 324 may cover the first sub connecting electrode 322.

In an embodiment, the first lower heater module 210 may be supplied with power by the second sub electrode LE2. The second sub electrode LE2 may be covered by a sixth insulator 326.

In an embodiment, the first connecting electrode CE1 may be deformed together with a deformation of the upper heater module HM1. Accordingly, the first connecting electrode CE1 may have a shape that may alleviate the thermal expansion stress.

In an embodiment, the second lower heater module 230 may be supplied with power by the third sub electrode LE3. The third sub electrode LE3 may be covered by a seventh insulator 328.

In an embodiment and referring to FIGS. 14 to 17, the first connecting electrode CE1 may have a curvature. In detail, the first connecting electrode CE1 according to the first embodiment may have an arc shape. The first connecting electrode CE1′ according to the second embodiment may have a meander shape. The meander shape may mean that the first connecting electrode CE1′ may have a shape similar to the letter ‘S’ and is connected. In another embodiment, the first connecting electrode CE1″ according to the third embodiment may include a plurality of metal sheets stacked in the third direction DR3.

However, the invention is not limited thereto. For example, the first connecting electrodes CE1, CE1′, or CE1″ may have various shapes that may alleviate the thermal expansion stress.

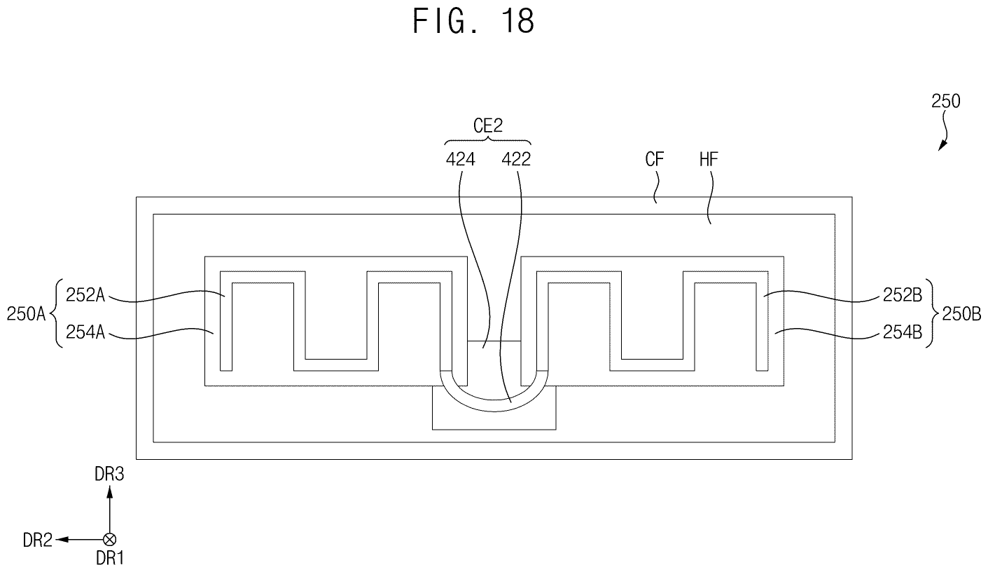

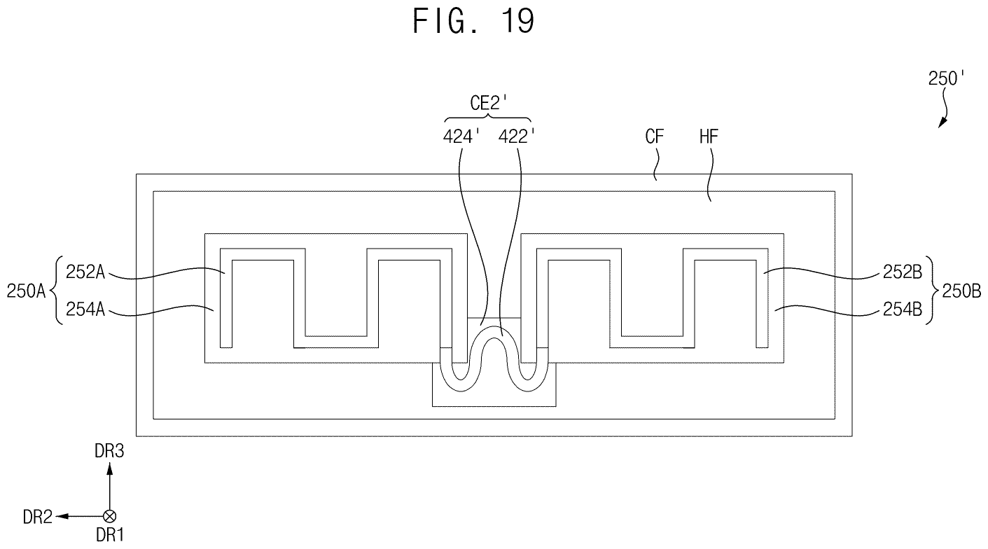

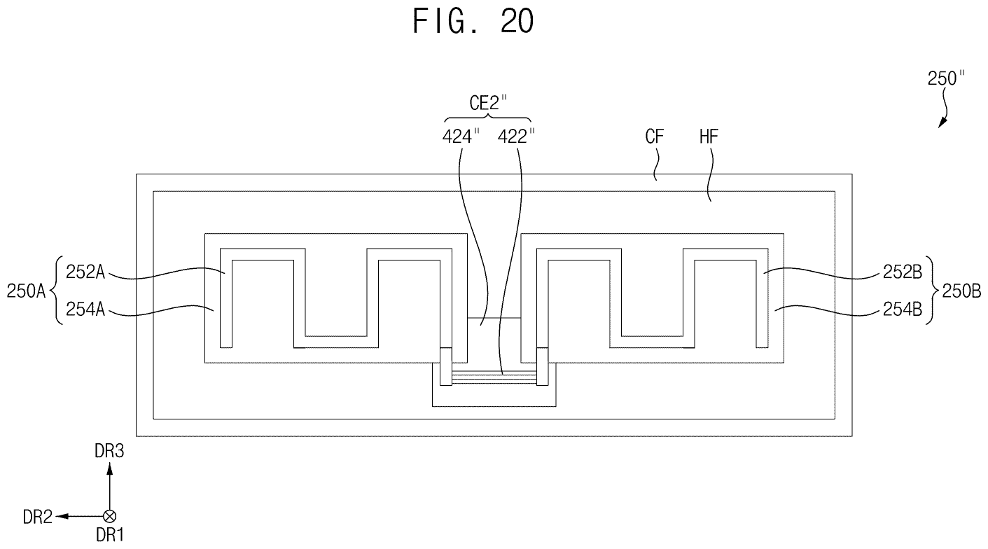

FIG. 18 is a front view illustrating a second connecting electrode of FIG. 7, according to a first embodiment. FIG. 19 is a front view illustrating a second connecting electrode of FIG. 7, according to a second embodiment. FIG. 20 is a front view illustrating a second connecting electrode of FIG. 7, according to a third embodiment.

In an embodiment, a shape and series connection structure of the second connecting electrodes CE2, CE2′, or CE2″ may be substantially a same shape as the shape and series connection structure of the first connecting electrodes CE1, CE1′, or CE1″. Hereinafter, descriptions that overlap with those described above with reference to FIGS. 1 to 17 will be omitted or simplified.

In an embodiment, a size of the insulator (e.g., the insulator IN in FIGS. 12, 13, 14, 15, 16, and 17) may be limited. For example, the insulator may have a width of about 400 mm. In this case, heaters having a size larger than the insulator might not be covered by the insulator. In this case, heaters having a size smaller than the insulator may be connected in series.

For example, in an embodiment and as shown in FIG. 7, the third lower heater module 250 having the two-tine fork (‘⊏’) shape may be formed by connecting three plate-shaped heater modules, and may also be formed by connecting two heater modules having a backward inverted “L” (‘¬’) shape. For example, when the third lower heater module 250 is formed by connecting the two heater modules having the backward inverted “L” (‘¬’) shape, the second connecting electrode CE2 may be disposed between the heater modules to connect the heater modules in series in the second direction DR2.

In an embodiment, the third lower heater module 250 may include a 31st lower heater module 250A and a 32nd lower heater module 250B. The 31st lower heater module 250A may include a 31st heater 252A and a 31st insulator 254A. The 32nd lower heater module 250B may include a 32nd heater 252B and a 32nd insulator 254B.

In an embodiment, the 31st lower heater module 250A and the 32nd lower heater module 250B may be connected in series by the second connecting electrode CE2. The second connecting electrode CE2 may include a second sub connecting electrode 422 and an eighth insulator 424. The eighth insulator 424 may cover the second sub connecting electrode 422.

The second connecting electrode CE2 may be deformed together with a deformation of the lower heater module HM2. Accordingly, the second connecting electrode CE2 may have a shape that may alleviate the thermal expansion stress.

In an embodiment, the second connecting electrode CE2 may have a curvature. In detail, the second connecting electrode CE2 according to the first embodiment may have an arc shape. The second connecting electrode CE2′ according to the second embodiment may have a meander shape. The meander shape may mean a shape in which the second connecting electrode CE2′ is similar shape like the letter ‘S’ and is connected. In another embodiment, second connecting electrode CE2″ according to the third embodiment may include a plurality of metal sheets stacked in the third direction DR3.

However, the invention is not limited thereto. For example, the second connecting electrodes CE2, CE2′, or CE2″ may have various shapes that may alleviate the thermal expansion stress.

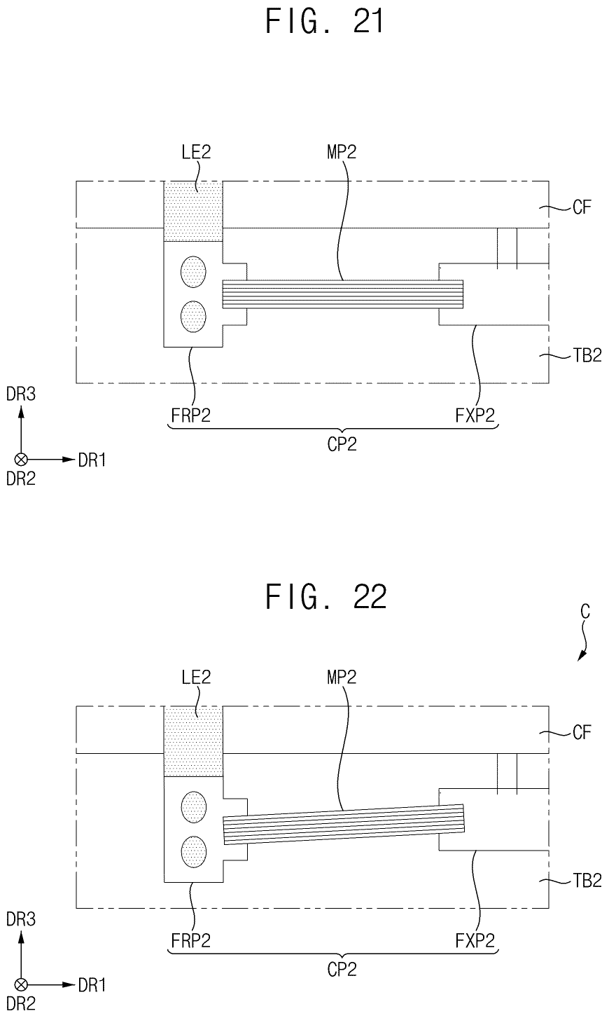

FIGS. 21 and 22 are enlarged views illustrating the second connector of FIG. 7, according to an embodiment.

In an embodiment, a structure in which the second sub electrode LE2 may be connected to the second terminal block TB2 may be substantially the same as a structure in which the first sub electrode LE1 is connected to the first terminal block TB1. Hereinafter, descriptions that overlap with those described above with reference to FIGS. 1 to 20 will be omitted or simplified.

Referring to FIGS. 3, 5, 7, 8, 21, and 22, in an embodiment, the second terminal block TB2 may be fixed to the second frame CF.

In an embodiment, the second terminal block TB2 may include a second fixed end FXP2 and a second free end FRP2. The second fixed end FXP2 is fixed to a bottom surface of the second frame CF and may be electrically connected to the power supply PS. The second free end FRP2 may be connected to the second sub electrode LE2, and the second free end FRP2 may move in the third direction DR3. In other words, the second sub electrode LE2 may be fixed to the second terminal block TB2 in a cantilever format. Accordingly, the second sub electrode LE2 may relieve the thermal expansion stress.

In an embodiment, the second fixed end FXP2 and the second free end FRP2 may be connected through the second connector CP2. In an embodiment, the second connector CP2 may include the plurality of metal sheets MP2 stacked in the third direction DR3. Accordingly, the thermal expansion stress may be relieved.

However, the invention is not limited thereto. For example, the second electrode L2 and the second connector CP2 may have various shapes that may alleviate the thermal expansion stress. Because of this, the lifespan of the heater module HM may be extended.

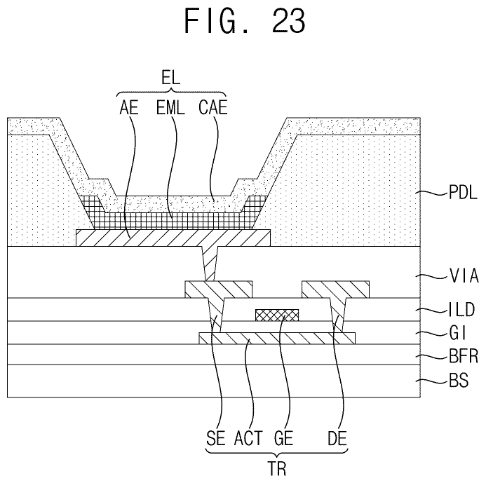

FIG. 23 is a cross-sectional view illustrating a pixel formed by a deposition process using the deposition apparatus including the deposition source, according to embodiments.

Referring to FIG. 23, a pixel PX may include a base substrate BS, a buffer layer BFR, a transistor TR, a gate insulating layer GI, an interlayer insulating layer ILD, a via insulating layer VIA, an emission device EL, and a pixel defining layer PDL.

In an embodiment, the transistor TR may include an active layer ACT, a gate electrode GE, a source electrode SE, and a drain electrode DE. The emission device EL may include a first electrode AE, an emission layer EML, and a second electrode CAE.

In an embodiment, the base substrate BS may include glass, quartz, plastic, or the like. For example, the base substrate BS may have flexible, bendable, and/or rollable characteristics.

In an embodiment, the buffer layer BFR may be disposed on the base substrate BS. The buffer layer BFR may include an inorganic insulating material. For example, the buffer layer BFR may include silicon oxide, silicon nitride, silicon oxynitride, or the like. The buffer layer BFR may block impurities so that the active layer ACT of the transistor TR is not damaged by the impurities diffused through the base substrate BS.

In an embodiment, the active layer ACT may be disposed on the buffer layer BFR. In an embodiment, the active layer ACT may include a silicon semiconductor. For example, the active layer ACT may include amorphous silicon, polycrystalline silicon, or the like. In another embodiment, the active layer ACT may include an oxide semiconductor. For example, the active layer ACT may include zinc oxide, zinc-tin oxide, zinc-indium oxide, indium oxide, titanium oxide, indium-gallium-zinc oxide, indium-zinc-tin oxide, or the like.

In an embodiment, the gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, tantalum oxide, or the like. The gate insulating layer GI may electrically insulate the active layer ACT and the gate electrode GE from each other.

In an embodiment, the gate electrode GE may be disposed on the gate insulating layer GI. The gate electrode GE may include a conductive material. For example, the gate electrode GE may include a metal, an alloy, a conductive metal oxide, a transparent conductive material, or the like. A gate signal may be applied to the gate electrode GE. The gate signal may turn on/off the transistor TR to adjust electrical conductivity of the active layer ACT.

In an embodiment, the interlayer insulating layer ILD may be disposed on the gate electrode GE. The interlayer insulating layer ILD may include an organic insulating material and/or an inorganic insulating material. The interlayer insulating layer ILD may electrically insulate the source electrode SE and drain electrode DE from the gate electrode GE.

In an embodiment, the source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, a transparent conductive material, or the like. Each of the source electrode SE and the drain electrode DE may electrically contact the active layer ACT through a contact hole (or contact opening) passing through the interlayer insulating layer ILD and the gate insulating layer GI.

In an embodiment, the via insulating layer VIA may be disposed on the source electrode SE and the drain electrode DE. The via insulating layer VIA may include an organic insulating material. For example, the via insulating layer VIA may include a polyacrylic resin, a polyimide resin, an acrylic resin, or the like. Accordingly, an upper surface of the via insulating layer VIA may be substantially flat.

In an embodiment, the first electrode AE may be disposed on the via insulating layer VIA. The first electrode AE may include a conductive material. For example, the first electrode AE may include a metal, an alloy, a conductive metal oxide, a transparent conductive material, or the like. The first electrode AE may electrically contact the source electrode SE or the drain electrode DE through a contact hole (or contact opening) penetrating the via insulating layer VIA.

In an embodiment, the pixel defining layer PDL may be disposed on the first electrode AE. The pixel defining layer PDL may include an organic insulating material. For example, the pixel defining layer PDL may include a polyacryl-based compound, a polyimide-based compound, or the like. The pixel defining layer PDL may partition the emission region of each of the pixels. The pixel defining layer PDL may include a pixel opening exposing the first electrode AE.

In an embodiment, the emission layer EML may be disposed on the first electrode AE in the pixel opening. The emission layer EML may include an organic emission material. In an embodiment, the emission layer EML may have a multi-layer structure including various functional layers. For example, the emission layer EML may include at least one of a hole injection layer, a hole transport layer, an electron transport layer, and an electron injection layer.

In an embodiment, the second electrode CAE may be disposed on the emission layer EML and may cover the pixel defining layer PDL.

In an embodiment, the emission layer EML may be formed by depositing the deposition material on the first electrode AE. For example, the emission layer EML may be formed by a deposition apparatus (e.g., a deposition apparatus DD of FIG. 1).

However, the invention is not limited thereto, and a layer formed through the deposition process may be functional layers, such as the hole transport layer, the electron transport layer, or the like. In another embodiment, the layer formed through the deposition process may be a capping layer, an encapsulation layer disposed on the second electrode CE, or the like

As described above, in an embodiment, the layer formed through the deposition process may have a small thickness distribution via the deposition apparatus DD of FIG. 1. As a result, the display quality of the display device including the pixel PX on which the deposition process is completed may be improved.

Embodiments of the invention may be applied to a display device and an electronic device including the display device such as computers, notebooks, cell phones, smart phones, smart pads, PMPs, PDAs, MP3 players, and/or the like, for example.

The invention should not be construed as being limited to the embodiments set forth herein. Rather, these embodiments are provided so that this disclosure will be thorough and complete and will fully convey the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims. Moreover, the embodiments or parts of the embodiments may be combined in whole or in part without departing from the scope of the invention.

What is claimed is:

1. A deposition source comprising:
a crucible that accommodates a deposition material;
a plurality of nozzles disposed on the crucible and spaced apart from each other along a first direction;
a housing accommodating the crucible and the plurality of nozzles;
a lower heater module disposed in an inner space of the housing and surrounding the crucible;
an upper heater module disposed on the lower heater module in the inner space of the housing;
a first electrode extending in a second direction crossing the first direction and connected to the lower heater module;
a second electrode extending in the second direction and connected to the upper heater module; and
a power supply electrically connected to the first electrode and the second electrode.

2. The deposition source of claim 1,
wherein the upper heater module includes a first upper heater module and a second upper heater module,
wherein the first upper heater module and the second upper heater module are spaced apart from each other in the first direction.

3. The deposition source of claim 2, further comprising:
a connecting electrode that connects the first upper heater module and the second upper heater module, wherein the connecting electrode is deformed together with a deformation of the upper heater module.

4. The deposition source of claim 3, wherein the connecting electrode has a curvature.

5. The deposition source of claim 3, wherein the connecting electrode includes a plurality of metal sheets stacked in a third direction that crosses each of the first direction and the second direction.

6. The deposition source of claim 1,
wherein the second electrode includes a third sub electrode and a fourth sub electrode,
wherein the third sub electrode is connected to a first end of the upper heater module and the fourth sub electrode is connected to a second end of the upper heater module, wherein the second end of the upper heater module is opposite to the first end of the upper heater module, and
wherein the third sub electrode and the fourth sub electrode transmit power of a preset amount to the upper heater module.

7. The deposition source of claim 1,
wherein the lower heater module includes a first lower heater module and a second lower heater module,
wherein the first lower heater module and the second lower heater module are spaced apart from each other in the first direction,
wherein the first electrode includes a first sub electrode and a second sub electrode,
wherein the first sub electrode is connected to a first end of the first lower heater module and transmits first power to the first lower heater module, and
wherein the second sub electrode is connected to a first end of the second lower heater module and transmits second power to the first lower heater module.

8. The deposition source of claim 7, wherein an amount of the first power and an amount of the second power are different from each other.

9. The deposition source of claim 7, further comprising:
a connecting electrode that connects the first lower heater module and the second lower heater module, wherein the connecting electrode is deformed together with a deformation of the lower heater module.

10. The deposition source of claim 9, wherein the connecting electrode has a curvature.

11. The deposition source of claim 9, wherein the connecting electrode includes a plurality of metal sheets stacked in a third direction that crosses each of the first direction and the second direction.

12. The deposition source of claim 1, further comprising:
a first frame disposed inside the housing and to which the upper heater module and the lower heater module are fixed;
a second frame disposed between the housing and the first frame; and
a terminal block disposed between the housing and the second frame and electrically connected to the power supply.

13. The deposition source of claim 12,
wherein the terminal block includes a fixed end and a free end,
wherein the fixed end is fixed to a bottom of the second frame and is electrically connected to the power supply and the free end is connected to the first electrode and is movable in a third direction that crosses each of the first direction and the second direction.

14. The deposition source of claim 13, further comprising:
a connector disposed between the fixed end and the free end,
wherein the connector includes a plurality of metal sheets stacked in the third direction.

15. The deposition source of claim 12,
wherein the terminal block includes a fixed end and a free end,
wherein the fixed end is fixed to a bottom of the second frame and is electrically connected to the power supply and the free end is connected to the second electrode and is movable in a third direction that crosses each of the first direction and the second direction.

16. The deposition source of claim 15, further comprising:
a connector disposed between the fixed end and the free end,
wherein the connector includes a plurality of metal sheets stacked in the third direction.

17. A deposition source comprising:
a crucible that accommodates a deposition material;
a plurality of nozzles disposed on the crucible and spaced apart from each other along a first direction;
a housing accommodating the crucible and the plurality of nozzles;
a plurality of lower heater modules disposed in an inner space of the housing and surrounding the crucible;
an upper heater module disposed on the lower heater module in the inner space of the housing;
a power supply electrically connected to the plurality of lower heater modules and the upper heater module; and
a controller that controls the power supply to apply power having a constant amount to the upper heater module.

18. The deposition source of claim 17, wherein each of the plurality of lower heater modules and the upper heater module are spaced apart by a predetermined distance.

19. The deposition source of claim 17,
wherein the plurality of lower heater modules include a first lower heater module and a second lower heater module, and
wherein the controller controls an amount of heat generated by each of the first lower heater module and the second lower heater module.

20. The deposition source of claim 17, wherein an amount of heat generated by the upper heater module is greater than the amount of heat generated by each of the plurality of lower heater modules.
